(19) United States
(12) Patent Application Publication
(10) Pub. No.: US 2007/0146751 A1
(43) Pub. Date: Jun. 28, 2007

(54) Color timing processes

(76) Inventor: Blase A. Theodore, Plantation, FL (US)

Correspondence Address: BRINKLE Y, MORGAN, SOLOMON, TATUM, STANLEY, LUNNY,;& CROSBY, LLP, 200 E. LAS OLAS BLVD, SUITE 1900, FORT LAUDERDALE, FL, 33301, US

(21) Appl. No.: 11/525,429

(22) Filed: Sep. 22, 2006

Related U.S. Application Data
(60) Provisional application No. 60/723,664, filed on Oct. 5, 2005.

(51) Int. Cl. G03F 3/08

(52) U.S. Cl. 358/1.9; 358/518

(57) ABSTRACT

A color timing process and system, the process comprising the steps of loading unexposed film into a master film track; transferring the images from a film negative onto the unexposed film to create a work print; using the work print to generate color timing corrections through key-framed vector data generated by a computer; associating a time code/frame code for each color timing corrected frame with the color timing corrections for that particular frame; saving the associated vector data as part of a vector data file; and creating a master print by projecting the color timing corrections through the film negative onto a new unexposed film. The system includes an apparatus for creating color timing corrections comprised of a recording sub-system, a preview sub-system, associated software and a computer processor and user interface.

### CROSS-REFERENCE TO RELATED APPLICATIONS

This application claims priority under 35 U.S.C. § 119(e) upon U.S. Provisional Application Ser. No. 60/723,664 filed on Oct. 5, 2005, which application is incorporated herein by reference.

### FIELD OF THE INVENTION

This invention relates to the processing of motion picture film, and more particularly relates to the color correction of images in motion picture film using a novel system and method therefor.

### BACKGROUND OF THE INVENTION

In motion picture feature and television production, many stages of the photographic imaging process are necessary to progress from the image capture stage until the final edited product is ready for distribution. In order to better explain modem editing processes, it is important to understand how film is manufactured and some basic procedures required in the actual production or shooting phase. Motion picture film is manufactured by coating a transparent support material with light sensitive emulsion layer(s), and an opaque antihalation layer coated either as a dyed layer between the light sensitive emulsion and the support or a pigmented or dyed layer on the side of the support opposite to the light sensitive emulsion. Many camera origination films employ a carbon black containing backing “remjet” layer as the antihalation layer. There are perforated sprocket holes at the edges of the film to allow for sprocket drives to pull the film through the motion picture cameras, printers, editing machines and projectors. Depending on the type of emulsion used, a positive or negative image (in color or black and white) will be produced on the film when it is properly exposed in the camera and subsequently processed at the film laboratory, wherein the antihalation layer is either removed (in the case of carbon black containing backing layers) or the dyes thereof rendered substantially colorless. Most all professional film production uses negative type film.

Once the original camera negative film is processed, the laboratory will then make a positive print of this film so that it may be viewed and edited. This print may be variously called the work print, direct print, or answer print. Upon completion of the editing process, the edited workprint is sent to a film cutter who will take the original camera negative or a print from the negative and cut it up to match the edited workprint. Positive prints, called release or master prints, can then be generated from this cut film and used for projection and/or transferred to videotape for showing on TV.

Typically, film editors wish to modify the image quality present in many of the frames on the film. Presently, there are two accepted practices for making such modifications. The first, known as optical color timing, requires the Filmmaker and Color Timist to watch the film together, taking notes about each scene, and how it should be ideally brightened and/or tinted to the film maker's satisfaction. Later, the film strip is separated into three separate primary color strips. By adjusting the intensity at which these individual layers are exposed, the Timist is able to control proportion of color.

The second technique is known as digital intermediate color timing (“DI”). When practicing DI, a cut and assembled film is scanned at ultra high resolution into extremely expensive and powerful computers. The digitized film is reviewed in real-time by the Filmmaker and Timist, and changes to any element can be made on the spot. Once the digital file is considered complete, it is fed through a film printing machine which laser etches the digital file back onto 35 mm film. EFilm Inc. currently holds the largest share of this market (roughly 40% of all DI films) and will have produced 30-40 films this year at an average cost of $250-$400 k per film. EFilm's success lies primarily in its ability to standardize the DI process and make it affordable (comparatively speaking). Therefore, there is a need for a color timing process which produces results similar to or yielded by DI processes, but which is both affordable economically and does not require immense data storage and computer processor capacity as is the case with DI technology.

### SUMMARY OF THE INVENTION

An embodiment of a color timing process in accordance with this invention comprises the steps of:

1. loading unexposed film into a master film track, and transferring the images from a film negative onto the unexposed film to create a work print;

2. using the work print to generate color timing corrections through key-framed vector data generated by a computer;

3. associating a time code/frame code for each color timing corrected frame with the color timing corrections for that particular frame and saving the associated vector data as part of a vector data file;

4. creating a master print by projecting the color timing corrections through the film negative onto a new unexposed film.

The apparatus for creating the color timing corrections in accordance with the invention includes a recording sub-system, a preview sub-system, associated software and a computer processor and user interface.

### BRIEF DESCRIPTION OF THE DRAWINGS

FIG. 1 is a system diagram of the apparatus adapted to be used in the preferred embodiment of my invention.

FIG. 2 is a flow diagram of a color timing process of the preferred embodiment of my invention.

### DETAILED DESCRIPTION OF THE INVENTION

The present description is directed in particular to elements forming part of, or cooperating more directly with, subsystems or steps performed in accordance with the invention. It is to be understood that elements not specifically shown or described may take various forms which are well known to those skilled in the art.

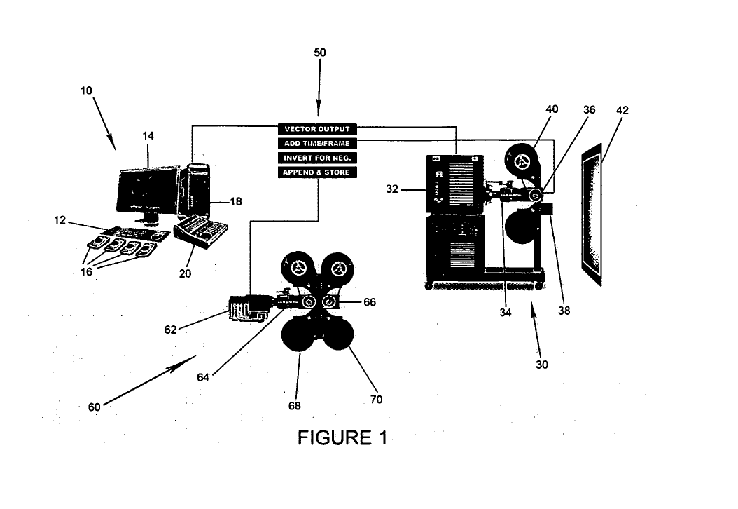

FIG. 1 shows a schematic layout of an apparatus utilized to practice the color timing correction processes of this invention. A computer system 10, which may incorporate a keyboard 12, a monitor 14, one or more trackball-type controllers 16, a central processing unit 18, a custom control device 20, (providing trackball, slider, knob, etc capability), is connected to a film image preview subsystem 30 via a series of software components designated by the reference number 50.

Preview subsystem 30 is comprised of a high output HD or 2 k digital projector 32 such as the Christie CP2000, custom adaptive optics 34 to permit correction for focus and to ensure that each image frame is in registry with the projector when the preview subsystem is in use, a frame counting/advancing mechanism 36, a frame scanning device 38, a film reel, track, an uptake mechanism 40 for the work print (not shown), and a projection screen 42. Scanning device 38 may be any one of a number of hardware arrangements used to digitally capture the image on the film frame in real time. Such an arrangement may utilize any type of frame digitizing device such as a frame scanning device (e.g. digital video or still camera or a film scanner) with backlighting capability to digitally capture the image which is electronically communicated to computer system 10.

A recording subsystem 60 communicates with software components 50 and is comprised of a low output digital projector 62 such as an HD or 2 k projector, such as those offered by either Sony or Christie, custom adaptive optics 64, a dual-track frame counting/advancing mechanism 66, a film reel, track, an uptake mechanism 68 for the film negative (not shown), and a film reel, track and uptake mechanism 70 for the master film (not shown). The adaptive optics function to register the digitally projected light source within the bounds of the targeted frame, as well as to slightly de-focus the light source and thereby blur any digital pixilation. The film reel, track, and uptake mechanism functions to provide a loaded roll of film with a controlled path of travel and storage, regardless of the direction of motion.

The software components used in the preview and recording subsystems can be stored and executed on any computer, but would likely be integrated into the computer system 10. The first software component, referred to as the tracing buffer module 52, loads raster image data of a scanned film frame into a temporary memory buffer and feeds it back to the user interface. This raster image is preferably not permanently stored but simply temporarily held in cache memory of the tracing buffer module as a tracing template and displayed on monitor 14 to permit the user to generate one or more matters of specific elements with the frame to be corrected. This allows users to accomplish more complicated procedures such as selective color mattes and animated mattes based on motion tracking. A secondary software component referred to as the vector storage/output module 54 first captures the vector data created by the computer system into a file, and then generates a rasterized image from it, which is fed to the preview projector. The final software component, referred to as the recording preparation module 56, appends timecode/framecode information obtained from the frame counting/advancing mechanism 36 to the vector data file and inverts the color information it contains to create a “negative” version of the file. Once the entire film has been reviewed for corrections, the negative file is complete and ready to be rasterized by this software module and fed to the recording subsystem 60.

To visualize the capabilities of the invention, a single frame of 35 mm film can be considered: in this example it will contain a scene composed of a tree on a hill with wilted grass under an overcast sky. For simplicity, one could avoid considering the film negative, which holds the inverse of the light projected, and refer only to the inter-positive. For simplicity, consider the projection of film in terms of purely subtractive color space (begins with white and digress to black). When a flashlight is shone through this frame, it projects a larger version of the image onto a screen.

Now imagine that the flashlight is replaced with a high definition computer projector, and the computer running it is told to project nothing more than a blank white screen. The projector would shine white light uniformly through the film frame, and project it against the screen the same way the flashlight would.

Perhaps when the image is projected, the wilted grass occupying the bottom half of the film frame and grey sky occupying the top half don't match the desired springtime scene. In that case, one could simply tell the computer to project blue and green light through the top and bottom half of the frame respectively thus creating the desired visual effect.

At this point, it may be decided that the beautiful scenery has stolen the attention of the audience, who should be focusing on the tree. To clarify this, one could tell the projector to decrease the amount of light projected in areas around the tree.

While this may be closer to the scene envisioned, perhaps it still does not carry the ‘nostalgic memory’ feel desired. It may be desired, therefore, to de-saturate the edges of the frame, leaving only the important parts of the scene in full color. Realizing that one can negate any color by projecting its opposite though it, one creates a dissolving ring of opposing color that circles the frame, accomplishing the desired effect. For example, one sees the color red when white light bounces off of a red object. That is because the object absorbs all the light except for the red portion of the spectrum which it rejects. This bounced light is what one sees. If one were to shine only green light on that red object (green is the opposite of red in color space) it would appear black. This is because there would be no red light for the object to bounce back. This example illustrates the core features of this invention in their simplest forms; an optical projection augmented by a digital light source.

The feature of blending digital and optical techniques for purposes of film color timing can be implemented through a system of this invention that offers an alternative to current color timing methods, with the following advantages:
Offers users a high degree of image control with virtually unlimited matting capability. A matte is essentially a mask of any shape or pattern that selects which part(s) of the image to be manipulated.
Higher film output quality than any color timing solution available
More affordable than any color timing solution currently available
Faster than any color timing solution available
“What You See is What You Get” (WYSIWYG) Security

Like the DI process it rivals, this method offers users a tremendous amount of control, allowing them to cut out, manipulate, and animate any shape or pattern they can draw. But rather than attempting to capture and then reproduce the tremendous amount of information available in a single film frame (as attempted in the DI process), this digital/optical hybrid solution simply digitally controls the source light that runs through it. There are several remarkable advantages to this approach in terms of both efficiency and quality, as outlined below.

Experts suggest that a digitized frame of 35 mm film is capable of holding data at a raster pixel resolution of 6144 pixels by 4608 pixels (“6 k”). Raster images are those created by breaking down a picture into columns and rows of pixels, where each pixel is assigned a separate color. Increasing the number of pixels that make up the picture increases the detail it is stored. Due to data bandwidth limitations of today's computers, the vast majority of DI processes are processed and printed at a pixel resolution of 2048 pixels by 1536 pixels (“2 k”), which means the final DI mastered film is 1/12^{th} the resolution of its original 6 k frame. Data rates for 2 k and 6 k frames are respectively 12 Mb and 150 Mb.

In the case of the instant invention, we are only concerning ourselves with what needs to be added, which can be defined in far more general terms. As such the invention proposes an alternative method of storing this corrective light information; key-framed (animated) vector data. Rather than breaking down an image into millions of pixels as raster images do, vector images are comprised of mathematical equations that symbolize patterns, colors, and positions. The most common example of this format is seen in Flash web animation and clip-art, but at a much lower bit-depth. In cases such as ours, they would require almost no memory to store and impose no bandwidth bottlenecks. This would be similar to writing down a statement like “make me a milkshake” instead of writing down several pages of extremely detailed steps needed to make a milkshake. The data bottleneck lies in moving all the instructions around, not in following them. When needed, the corrective light data could be generated instantly on a per frame basis at ultra-high resolutions using off the shelf computer systems.

The method of this invention can deliver up to twelve times the image resolution of a DI master print and replace an entire room full of proprietary data servers with a single workstation.

In a traditional color timing model, the processing lab takes a cut negative and creates 3 primary color strips from it. From those copies additional corrective copies are made, and so the final master print is several copies from the original. With the instant method, all final changes can be applied using the original negative, creating a 1^{st} generation master-print. This alleviates any image degradation that would typically result from making copies of copies.

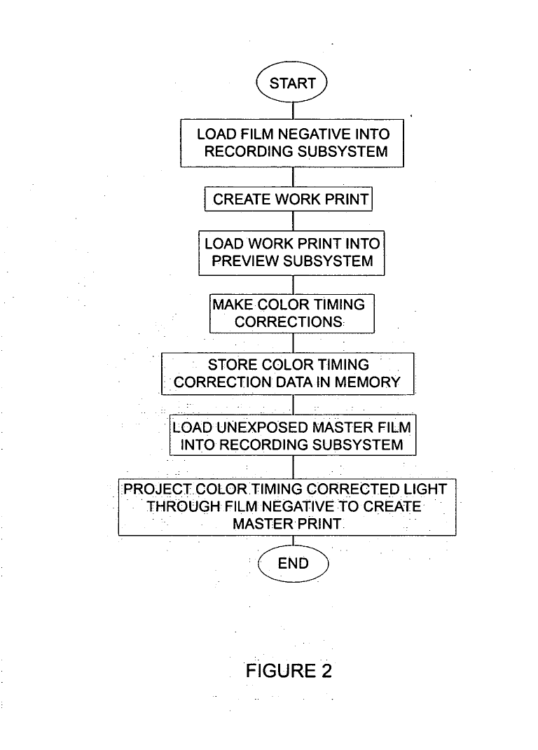

Referring now to FIG. 2, the preferred embodiment of the process of the invention is disclosed. A film is created by recording one or more scenes onto successive image frames of a motion picture film. A film negative (not shown) is created from this recording. The film negative is loaded into the film reel, track and uptake mechanism 68 of the recording subsystem 60. An unexposed film (not shown), of equal or greater length to the film negative, is loaded into the film reel, track and uptake mechanism 70 of recording subsystem 60. The recording subsystem 60 is set to “duplication mode”, such that both film tracks advance synchronously frame by frame in parallel. As the recording projector 62 projects constant white light through the film negative and exposes the unexposed film, the recording system generates a viewable copy (aka “workprint”) of the film. The developed work print is then loaded into the film reel, track and uptake mechanism 38 of the preview subsystem 30.

The user can then run the projector 32 and view the projected image on projection screen 42, to determine if any color modifications are to be made to the film. If so, the user programs the corrective light vector data into the computer system 10 through the control device 20, trackballs 16 and/or keyboard 12, using images scanned from the film scanning device 38 and loaded from the tracing buffer 52 as a guide onto the monitor 14. This information is fed to the vector storage/output module 54, which appends the corrective light data to a vector file, rasterizes it instantly at ultra-high resolutions, and feeds the resulting image signal to the preview projector 32. The projector sends the corrected light through the work print residing in reel, track and uptake mechanism 38 onto the screen 40. Corrections are made on a frame-by-frame basis at key points in the timeline. For example, a 100 frame scene filmed by a camera while panning might require a corrective entry for frames 1 and 100, whereas the corrective data for the remaining frames can be interpolated by the software subsystem 50 for preview and recording at the time of rasterization.

As the frame counting/advancing mechanism 36 moves the film forward, it feeds the timecode/framecode information associated with each frame to the recording preparation module 56, which appends the information to the vector file.

Once all of the modifications to the color timing have been calculated for the work print, new unexposed film is loaded into the master film reel, track and uptake mechanism 70. By synchronizing the timecode/framecode information stored in recording preparation module 56 with the timecode/framecode information obtained from the counting/advancing mechanism 66, the recording subsystem 60 will advance the film negative in mechanism 68 in parallel with the new, unexposed, film in mechanism 70, and simultaneously project from recording projector 62 the inverted corrective light data obtained from recording preparation module 56 through the film negative and onto the new, unexposed, master film in mechanism 70. The resulting positive master print will thereby chemically reflect the light data corrections created using the preview subsystem.

I claim:

1. A color timing process and system, the process comprising the steps of: loading unexposed film into a master film track; transferring the images from a film negative onto the unexposed film to create a work print; using the work print to generate color timing corrections through key-framed vector data generated by a computer; associating a time code/frame code for each color timing corrected frame with the color timing corrections for that particular frame; saving the associated vector data as part of a vector data file; and creating a master print by projecting the color timing corrections through the film negative onto a new unexposed film.
